(19) United States
(12) Patent Application Publication
(10) Pub. No.: US 2024/0421068 A1
(43) Pub. Date: Dec. 19, 2024

(54) SEMICONDUCTOR DEVICES HAVING CAPACITOR STRUCTURES AND SEMICONDUCTOR INTEGRATED CIRCUITS HAVING THE SAME

(71) Applicant: SAMSUNG ELECTRONICS CO., LTD., SUWON-SI (KR)

(72) Inventors: Myoungsoo KIM, Suwon-si (KR); Minyoung KIM, Suwon-si (KR)

(21) Appl. No.: 18/738,100

(22) Filed: Jun. 10, 2024

(30) Foreign Application Priority Data
Jun. 13, 2023 (KR) 10-2023-0075313

(51) Int. Cl. H01L 23/522; H01L 27/02; H01L 27/06

(52) U.S. Cl. CPC H01L 23/5223; H01L 23/5228; H01L 27/0248; H01L 27/0629; H01L 28/75

(57) ABSTRACT

A semiconductor device including: a device layer on a substrate; an interconnection layer disposed on the device layer, wherein the interconnection layer includes conductive interconnections forming a plurality of layers; and first and second capacitor structures disposed inside the interconnection layer. Each of the first and second capacitor structures includes: electrode layers spaced apart from each other in a vertical direction and forming three or more layers; dielectric layers between the electrode layers; conductive vias respectively connected to one of the electrode layers and extending vertically; a first connection terminal electrically connected to a lowermost electrode layer; and a second connection terminal electrically connected to at least one of the electrode layers, wherein the first capacitor structure and the second capacitor structure include the same number of electrode layers, and wherein a first capacitance of the first capacitor structure is different from a second capacitance of the second capacitor structure.

### CROSS-REFERENCE TO RELATED APPLICATION(S)

This application claims priority under 35 U.S.C. § 119 to Korean Patent Application No. 10-2023-0075313 filed on Jun. 13, 2023 in the Korean Intellectual Property Office, the disclosure of which is incorporated by reference herein in its entirety.

### TECHNICAL FIELD

The present inventive concept relates to a semiconductor device including a capacitor structure, and a semiconductor integrated circuit device including the same.

### DISCUSSION OF RELATED ART

As the demand for higher performance, speed, and multifunctionality in semiconductor devices grows, so does their degree of integration. To manufacture semiconductor devices that align with this trend of higher integration, there is a need to create patterns with fine widths or separation distances. In addition, there is also a need for a higher degree of integration of the passive elements within these semiconductor devices.

### SUMMARY

An embodiment of the present inventive concept provides a semiconductor device having a capacitor structure capable of implementing various capacitances.

An embodiment of the present inventive concept provides a semiconductor device including: a device layer on a substrate; an interconnection layer disposed on the device layer, wherein the interconnection layer includes conductive interconnections forming a plurality of layers; and first and second capacitor structures disposed inside the interconnection layer. Each of the first and second capacitor structures includes: electrode layers spaced apart from each other in a vertical direction and forming three or more layers; dielectric layers between the electrode layers; conductive vias respectively connected to one of the electrode layers and extending vertically; a first connection terminal electrically connected to a lowermost electrode layer; and a second connection terminal electrically connected to at least one of the electrode layers, wherein the first capacitor structure and the second capacitor structure include the same number of electrode layers, and wherein a first capacitance of the first capacitor structure is different from a second capacitance of the second capacitor structure.

An embodiment of the present inventive concept provides a semiconductor integrated circuit device including: an input/output pad; a data processor configured to transmit and receive a signal to and from the input/output pad; and an electrostatic discharge protection circuit connecting the input output pad and the data processor, wherein the electrostatic discharge protection circuit includes: a device layer on a substrate; an interconnection layer disposed on the device layer, wherein the interconnection layer includes conductive interconnections forming a plurality of layers; capacitor structures disposed inside the interconnection layers; and resistance structures disposed inside the interconnection layer, wherein each of the capacitor structures includes electrode layers spaced apart from each other in a vertical direction and forming three or more layers, and dielectric layers between the electrode layers, the capacitor structures include a first capacitor structure and a second capacitor structure, having different capacitances, and each of the resistance structures includes electrode layers spaced apart from each other in a vertical direction and forming three or more layers, and dielectric layers between the electrode layers of the resistance structure.

An embodiment of the present inventive concept provides a semiconductor device including: a device layer on a substrate; an interconnection layer disposed on the device layer, and including conductive interconnections forming a plurality of layers; and capacitor structures and resistance structures, disposed on the same vertical level inside the interconnection layer, wherein each of the capacitor structures includes electrode layers spaced apart from each other in a vertical direction and forming three or more layers, and a first connection terminal and a second connection terminal, disposed on the electrode layers and electrically connected to at least one of the electrode layers, each of the resistance structures includes electrode layers spaced apart from each other in a vertical direction and forming three or more layers, and a first resistance terminal and a second resistance terminal, disposed on the electrode layers of the resistance structure and electrically connected to at least one of the electrode layers of the resistance structure, the first connection terminal, the second connection terminal, the first resistance terminal, and the second resistance terminal are disposed on the same vertical level as each other, the capacitor structures include a first capacitor structure and a second capacitor structure, including the same number of electrode layers, and a first capacitance of the first capacitor structure is different from a second capacitance of the second capacitor structure.

### BRIEF DESCRIPTION OF THE DRAWINGS

The above and other features of the present inventive concept will be more clearly understood from the following detailed description, taken in conjunction with the accompanying drawings,

in which:

FIG. 1 is a cross-sectional view of a semiconductor device according to example embodiments of the present inventive concept.

FIGS. 2 to 8 illustrate capacitor structures according to example embodiments of the present inventive concept.

FIGS. 9 to 11 illustrate capacitor structures according to example embodiments of the present inventive concept.

FIG. 12 is a cross-sectional view of a semiconductor device according to an example embodiment of the present inventive concept.

FIG. 13 illustrates a resistance structure according to an example embodiment of the present inventive concept.

FIG. 14 is a cross-sectional view of a semiconductor device according to an example embodiment of the present inventive concept.

FIG. 15 is a configuration diagram illustrating a semiconductor integrated circuit device including a semiconductor device according to an embodiment of the present inventive concept.

FIG. 16 is a configuration diagram illustrating a semiconductor integrated circuit device including a semiconductor device according to an embodiment of the present inventive concept.

FIG. 17 is a configuration diagram illustrating a semiconductor integrated circuit device including a semiconductor device according to an embodiment of the present inventive concept.

### DETAILED DESCRIPTION OF THE EMBODIMENTS

Example embodiments will now be described more fully hereinafter with reference to the accompanying drawings; however, the present inventive concept may be embodied in many different forms and should not be construed as limited to the embodiments set forth herein.

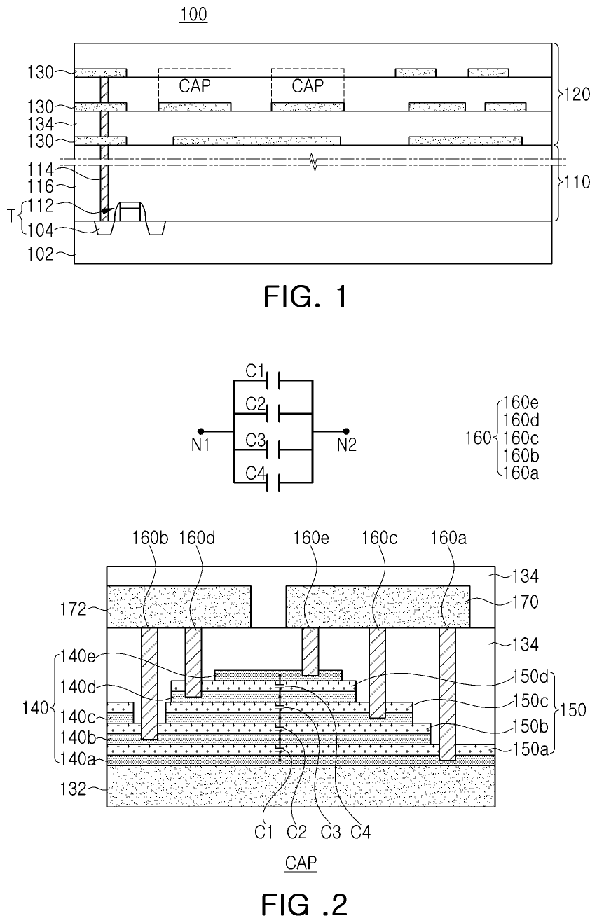

FIG. 1 is a cross-sectional view of a semiconductor device according to example embodiments.

Referring to FIG. 1, a semiconductor device 100 according to an embodiment may include a substrate 102, a device layer 110, an interconnection layer 120, and a capacitor structure CAP.

The substrate 102 may include a semiconductor material, such as a group IV semiconductor, a group III-V compound semiconductor, or a group II-VI compound semiconductor. For example, the group IV semiconductor may include silicon, germanium, or silicon-germanium.

The device layer 110 may be disposed on the substrate 102. The device layer 110 may include a transistor T, a via 114, and an insulating layer 116. The transistor T may include source/drain regions 104 and a gate structure 112.

The source/drain regions 104 may be disposed on the substrate 102, and may be disposed on both sides of the gate structure 112. The source/drain regions 104 may extend into the substrate 102 while the gate structure 112 may extend into the device layer 110. The source/drain regions 104 may include n-type impurities or p-type impurities.

The via 114 may be connected to the transistor T. For example, the via 114 may electrically connect the transistor T to the interconnection layer 120. The via 114 may extend vertically, and may be in contact with a source/drain region 104. For example, the via 114 may be disposed on one of the source/drain regions 104 next to the gate structure 112. The insulating layer 116 may cover the substrate 102, the transistor T, and the via 114.

The interconnection layer 120 may include a conductive interconnection 130 and an interlayer insulating layer 134. Conductive interconnections 130 may extend horizontally, and may be arranged as layers. For example, the conductive interconnections 130 may be spaced apart from each other in a horizontal direction, and the conductive interconnections 130 may be partially spaced apart from each other in a vertical direction. At least one of the conductive interconnections 130 may be electrically connected to the transistor T through the via 114. The conductive interconnection 130 may include a metal such as copper (Cu), aluminum (Al), silver (Ag), tin (Sn), gold (Au), nickel (Ni), lead (Pb), titanium (Ti), chromium (Cr), or tungsten (W). For example, the conductive interconnection 130 may include aluminum (Al).

The interlayer insulating layer 134 may be arranged as layers, and may cover the conductive interconnections 130. The interlayer insulating layer 134 may include an insulating material such as phosphor silicate glass (PSG), borophosphosilicate glass (BPSG), undoped silica glass (USG), spin on glass (SOG), tetra ethyl ortho silicate (TEOS), plasma enhanced-TEOS (PE-TEOS), or high density plasmachemical vapor deposition (HDP-CVD).

Capacitor structures CAP may be disposed inside the interconnection layer 120. The capacitor structures CAP may be formed with the conductive interconnections 130. For example, the capacitor structures CAP may be disposed on the same vertical level as each other, and may be spaced apart from each other in a horizontal direction. The number and arrangement of the capacitor structures CAP illustrated in FIG. 1 are illustrative, and are not limited thereto. For example, the number of capacitor structures CAP may be greater than two.

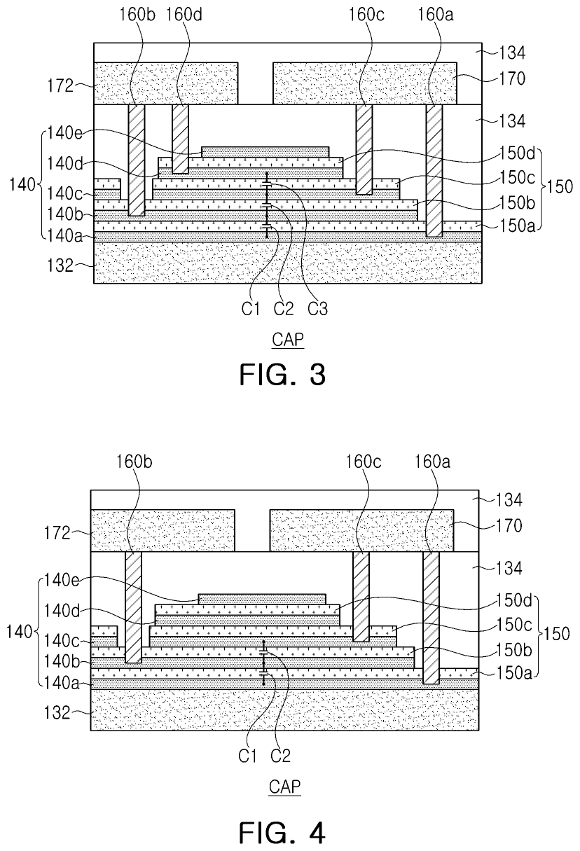

FIGS. 2 to 8 illustrate capacitor structures according to example embodiments. At least one of the capacitor structures illustrated in FIG. 1 may correspond to capacitor structures of FIGS. 2 to 8.

Referring to FIG. 2, a capacitor structure CAP may include electrode layers 140, dielectric layers 150, conductive vias 160, a first connection terminal 170, and a second connection terminal 172. The electrode layers 140 may extend in a horizontal direction. In an embodiment, the capacitor structure CAP may include three or more electrode layers 140. For example, the electrode layers 140 may include a first electrode layer 140a, a second electrode layer 140b, a third electrode layer 140c, a fourth electrode layer 140d, and a fifth electrode layer 140e, spaced apart from each other in a vertical direction. The electrode layers 140 may include a conductive material, and may include a material different from that of the conductive interconnection 130.For example, the electrode layers 140 may include titanium nitride (TiN), tantalum nitride (TaN), tungsten nitride (WN), or a combination thereof. In an embodiment, the electrode layers 140 may include titanium nitride (TiN).

The dielectric layers 150 may be disposed between the electrode layers 140. For example, the dielectric layers 150 may include a first dielectric layer 150a between the first electrode layer 140a and the second electrode layer 140b, a second dielectric layer 150b between the second electrode layer 140b and the third electrode layer 140c, a third dielectric layer 150c between the third electrode layer 140c and the fourth electrode layer 140d, and a fourth dielectric layer 150d between the fourth electrode layer 140d and the fifth electrode layer 140e. A dielectric layer 150 may not be disposed on an upper surface of the fifth electrode layer 140e, which may be the uppermost electrode layer. The electrode layers 140 and the dielectric layers 150 may be covered by an interlayer insulating layer 134. For example, the interlayer insulating layer 134 may be in direct contact with an upper surface of the fifth electrode layer 140e. A dielectric layer 150 may include SiN, ZrO₂, HfO₂, TiO₂, Ta₂O₅, SrTiO₃, CaTiO₃, LaALO₃, BaZrO₃, BaSrTiO₃, BaZrTiO₃, SrZrTiO₃, or combinations thereof.

The conductive vias 160 may extend vertically through the interlayer insulating layer 134, and may make contact with a corresponding one of the electrode layers 140. For example, the conductive vias 160 may include a first conductive via 160a, a second conductive via 160b, a third conductive via 160c, a fourth conductive via 160d, and a fifth conductive via 160e, contacting the first electrode layer 140a, the second electrode layer 140b, the third electrode layer 140c, the fourth electrode layer 140d, and the fifth electrode layer 140e, respectively. Some of the conductive vias 160 may pass through the dielectric layer 150 disposed on the electrode layer 140.

Furthermore, the first to fifth conductive vias 160a-160e may penetrate into their corresponding one of the first to fifth electrode layers 140a-140e.

The first connection terminal 170 and the second connection terminal 172 may be disposed on and connected to the conductive vias 160. The first connection terminal 170 and the second connection terminal 172 may be electrically connected to the corresponding electrode layers 140 through the conductive vias 160. For example, the first connection terminal 170 may be electrically connected to the first electrode layer 140a, the third electrode layer 140c, and the fifth electrode layer 140e, through the first conductive via 160a, the third conductive via 160c, and the fifth conductive via 160e. The second connection terminal 172 may be electrically connected to the second electrode layer 140b and the fourth electrode layer 140d through the second conductive via 160b and the fourth conductive via 160d. The first connection terminal 170 and the second connection terminal 172 may correspond to both nodes N1 and N2 of an equivalent capacitor formed by the capacitor structure CAP.

In an embodiment, the capacitor structure CAP between the first connection terminal 170 and the second connection terminal 172 may have a structure in which capacitor units are connected in parallel. In this case, the capacitor unit may refer to a capacitor formed by two vertically adjacent electrode layers 140 and a dielectric layer 150 therebetween. For example, the first electrode layer 140a, the second electrode layer 140b, and the first dielectric layer 150a between the first connection terminal 170 and the second connection terminal 172 may form a first capacitor C1 as a capacitor unit. Specifically, since the first conductive via 160a is in contact with the first electrode layer 140a and the first connection terminal 170, the first connection terminal 170 may be connected to the first electrode layer 140a with an equal potential. Additionally, since the second conductive via 160b is in contact with the second electrode layer 140b and the second connection terminal 172, the second connection terminal 172 may be connected to the second electrode layer 140b with an equal potential. The first electrode layer 140a, the second electrode layer 140b, and the first dielectric layer 150a therebetween may form the first capacitor C1, and may have a capacitance C. The first capacitor C1 may be the lowermost capacitor of the capacitor structure CAP.

The second electrode layer 140b, the third electrode layer 140c, and the second dielectric layer 150b therebetween may form a second capacitor C2. The third electrode layer 140c, the fourth electrode layer 140d, and the third dielectric layer 150c therebetween may form a third capacitor C3. The fourth electrode layer 140d, the fifth electrode layer 140e, and the fourth dielectric layer 150d therebetween may form a fourth capacitor C4. The fourth capacitor C4 may be the uppermost capacitor of the capacitor structure CAP. In an embodiment, the second capacitor C2, the third capacitor C3, and the fourth capacitor C4 may have a capacitance C, respectively, like the first capacitor C1. Since the first conductive via 160a, the third conductive via 160c, and the fifth conductive via 160e are in contact with the first connection terminal 170, the first electrode layer 140a, the third electrode layer 140c, and the fifth electrode layer 140e may be connected to the first connection terminal 170 with an equal potential. Similarly, the second electrode layer 140b and the fourth electrode layer 140d may be connected to the second connection terminal 172 with an equal potential. Therefore, the first capacitor C1, the second capacitor C2, the third capacitor C3, and the fourth capacitor C4 may all be connected in parallel, and capacitance of an equivalent capacitor formed by the capacitor structure CAP may be 4C.

In an embodiment, the capacitor structure CAP may further include a lower interconnection 132. The first electrode layer 140a, which is the lowermost electrode layer, may be disposed on an upper surface of the lower interconnection 132. The lower interconnection 132 may be electrically connected to the first electrode layer 140a, which is the lowermost electrode layer, and may function as an electrode of the capacitor structure CAP. The lower interconnection 132 may include a material identical to that of the conductive interconnections 130, and may have a vertical thickness, substantially equal to a vertical thickness of each of the conductive interconnections 130. The lower interconnection 132 may be located on the same vertical level as at least one of the conductive interconnections 130. The first connection terminal 170 and the second connection terminal 172 may also be located on the same vertical level as at least one of the conductive interconnections 130.

In some embodiments, shapes of the electrode layers 140 and the dielectric layers 150 may change so that the first capacitor C1, the second capacitor C2, the third capacitor C3, and the fourth capacitor C4 have the same capacitance. In some embodiments, planar areas and thicknesses of the electrode layers 140 may be different from each other. For example, a planar area of the first electrode layer 140a may be smaller than a planar area of the fifth electrode layer 140e, and a thickness of the first electrode layer 140a may be greater than a thickness of the fifth electrode layer 140e. Similarly, planar areas and thicknesses of the dielectric layers 150 may be different from each other. Alternatively, the planar areas and the thicknesses of the electrode layers 140 may be equal to each other, and the planar areas and the thicknesses of the dielectric layers 150 may be equal to each other.

Referring to FIG. 3, a capacitor structure CAP may include three or more electrode layers 140. Compared to the capacitor structure CAP of FIG. 2, the capacitor structure CAP of FIG. 3 may not include a fifth conductive via 160e connected to a fifth electrode layer 140e. In other words, the fifth electrode layer 140e may not be connected to a conductive via 160. In addition, the capacitor structure CAP includes a first conductive via 160a, a second conductive via 160b, a third conductive via 160c, and a fourth conductive via 160d extending vertically from a first connection terminal 170 and a second connection terminal 172. In the current embodiment, a first electrode layer 140a, a second electrode layer 140b, and a first dielectric layer 150a therebetween may form a first capacitor C1. The second electrode layer 140b, a third electrode layer 140c, and a second dielectric layer 150b therebetween may form a second capacitor C2. The third electrode layer 140c, a fourth electrode layer 140d, and a third dielectric layer 150c therebetween may form a third capacitor C3. In an embodiment, each of the first capacitor C1, the second capacitor C2, and the third capacitor C3 may have a capacitance C, respectively. Therefore, the first capacitor C1, the second capacitor C2, and the third capacitor C3 may all be connected in parallel, and capacitance of an equivalent capacitor formed by the capacitor structure CAP may be 3 C.

Referring to FIG. 4, a capacitor structure CAP may include three or more electrode layers 140. Compared to the capacitor structure CAP of FIG. 2, the capacitor structure CAP of FIG. 4 may not include a fourth conductive via 160d and a fifth conductive via 160e, and may include a first conductive via 160a, a second conductive via 160b, and a third conductive via 160c. In this case, the fourth and fifth electrode layers 140d and 140e may not be connected to a conductive via 160. As described above, a first electrode layer 140a, a second electrode layer 140b, and a third electrode layer 140c, and dielectric layers 150 therebetween may form a first capacitor C1 and a second capacitor C2, connected in parallel. Therefore, capacitance of an equivalent capacitor provided by the capacitor structure CAP may be 2 C.

Referring to FIG. 5, a capacitor structure CAP may include three or more electrode layers 140. The capacitor structure CAP of FIG. 5 may include a first conductive via 160a and a second conductive via 160b. Here, the third to fifth electrode layers 140c-140e may not be connected to a conductive structure; therefore, only a first electrode layer 140a, a second electrode layer 140b, and a first dielectric layer 150a therebetween may form a first capacitor C1, and may have a capacitance C. Therefore, capacitance of an equivalent capacitor formed by the capacitor structure CAP may be C.

Referring to FIG. 6, a capacitor structure CAP may include three or more electrode layers 140. The capacitor structure CAP of FIG. 6 may include a first conductive via 160a and a third conductive via 160c. A first electrode layer 140a, a second electrode layer 140b, a third electrode layer 140c, a first dielectric layer 150a, and a second dielectric layer 150b may form a first capacitor C1 and a second capacitor C2, connected in series. For example, the first capacitor C1 and the second capacitor C2 may share the second electrode layer 140b. Capacitance of the first capacitor C1 and capacitance of the second capacitor C2 may be C, respectively. Therefore, capacitance of an equivalent capacitor formed by the capacitor structure CAP may be 1/2*C. Referring to FIG. 7, a capacitor structure CAP may include three or more electrode layers

140. The capacitor structure CAP of FIG. 7 may include a first conductive via 160a and a fourth conductive via 160d. A first electrode layer 140a, a second electrode layer 140b, a third electrode layer 140c, a fourth electrode layer 140d, a first dielectric layer 150a, a second dielectric layer 150b, and a third dielectric layer 150c may form a first capacitor C1, a second capacitor C2, and a third capacitor C3, connected in series. Therefore, capacitance of an equivalent capacitor formed by the capacitor structure CAP may be 1/3*C.

Referring to FIG. 8, a capacitor structure CAP may include three or more electrode layers 140. The capacitor structure CAP of FIG. 8 may include a first conductive via 160a and a fifth conductive via 160e. A first electrode layer 140a, a second electrode layer 140b, a third electrode layer 140c, a fourth electrode layer 140d, a fifth electrode layer 140e, a first dielectric layer 150a, a second dielectric layer 150b, a fourth dielectric layer 150d, and a fifth dielectric layer 150e may form a first capacitor C1, a second capacitor C2, a third capacitor C3, and a fourth capacitor C4, connected in series. Therefore, capacitance of an equivalent capacitor formed by the capacitor structure CAP may be 1/4*C.

In an embodiment, some of the electrode layers 140 of the capacitor structure CAP illustrated in FIGS. 3 to 8 may not be electrically connected to both a first connection terminal 170 and a second connection terminal 172.

As described above, the semiconductor device 100 illustrated in FIG. 1 may include a plurality of capacitor structures CAP, and each of the capacitor structures CAP may be one of the capacitor structures CAP illustrated in FIGS. 2 to 8. As illustrated in FIGS. 2 to 4, capacitor units may be connected in parallel within a smaller area, allowing for the implementation of a high-density capacitor compared to a capacitor composed of two electrode layers 140. Therefore, a size of the semiconductor device 100 may be reduced.

In addition, as illustrated in FIGS. 6 to 8, capacitor units may be connected in series, allowing for the implementation of a capacitor with a high internal voltage, in contrast to a capacitor composed of two electrode layers 140. For example, when a voltage of the first electrode layer 140a and a voltage of the third electrode layer 140c are 0V and 10V, respectively, in the capacitor structure CAP illustrated in FIG. 6, a voltage of the second electrode layer 140b may be 5V in the capacitor structure CAP illustrated in FIG. 6. A difference in voltage between the first electrode layer 140a and the second electrode layer 140b as well as between the second electrode layer 140b and the third electrode layer 140c, may be half a difference in voltage between the first connection terminal 170 and the second connection terminal 172. Therefore, an internal voltage of the capacitor structure CAP may be twice that of an internal voltage of the capacitor unit. Similarly, internal voltages of the capacitor structures CAP of FIGS. 7 and 8 may be 3 times and 4 times an internal voltage of the capacitor unit, respectively. In this manner, in a structure in which capacitor units are connected in series, a capacitor having a high internal voltage may be implemented. Therefore, since the capacitor structure CAP of the semiconductor device 100 of the present inventive concept may include an electrode layer 140 comprised of three or more layers, capacitors having various capacitances may be implemented, as illustrated in FIGS. 2 to 8.

In an embodiment, the capacitor structures CAP of FIGS. 2 to 8 may be formed simultaneously. For example, after alternately stacking electrode materials and dielectric materials on a lower interconnection 132, at least one patterning process may be performed. The electrode material and the dielectric material may be etched by the patterning process to form the electrode layer 140 and the dielectric layer 150. After an interlayer insulating layer 134 is formed, a contact hole may be formed by an anisotropic etching process using the electrode layer 140 as an etch stop layer. Conductive vias 160 may be formed by forming a conductive material in the contact hole. Therefore, conductive vias 160 having different heights may be simultaneously formed.

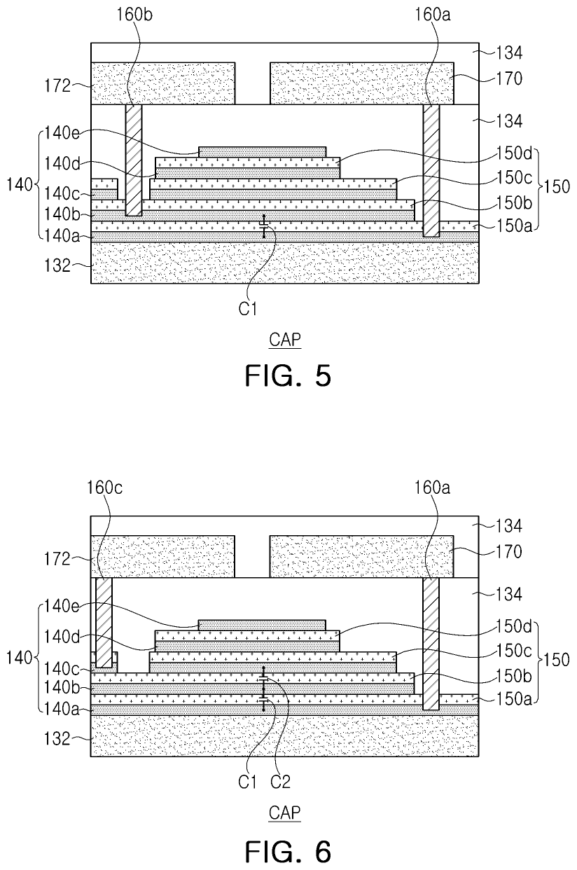

FIGS. 9 to 11 illustrate capacitor structures according to example embodiments. At least one of the capacitor structures illustrated in FIG. 1 may correspond to capacitor structures of FIGS. 9 to 11. Each of the capacitor structures of FIGS. 9 to 11 may include three electrode layers.

Referring to FIG. 9, electrode layers 140 and conductive vias 160 of a capacitor structure CAP may have the same or similar structures as those of the capacitor structure CAP of FIG. 4. A first electrode layer 140a, a second electrode layer 140b, and a third electrode layer 140c, and dielectric layers 150 therebetween may form a first capacitor C1 and a second capacitor C2, connected in parallel. Therefore, capacitance of an equivalent capacitor formed by the capacitor structure CAP may be 2C.

Referring to FIG. 10, electrode layers 140 and conductive vias 160 of a capacitor structure CAP may have the same or similar structures as those of the capacitor structure CAP of FIG. 5. A first electrode layer 140a, a second electrode layer 140b, and a first dielectric layer 150a therebetween may form a first capacitor C1. Therefore, capacitance of an equivalent capacitor formed by the capacitor structure CAP of FIG. 10 may be C.

Referring to FIG. 11, electrode layers 140 and conductive vias 160 of a capacitor structure CAP may have the same or similar structures as those of the capacitor structure CAP of FIG. 4. A first electrode layer 140a, a second electrode layer 140b, and a third electrode layer 140c, the first dielectric layer 150a and the second dielectric layer 150b may form a first capacitor C1 and a second capacitor C2, connected in series. Therefore, capacitance of an equivalent capacitor formed by the capacitor structure CAP may be 1/2*C.

In an embodiment, the capacitor structures CAP of FIGS. 9 to 11 may be simultaneously formed similarly to a method of forming the capacitor structures CAP of FIGS. 2 to 8. In addition, the capacitor structures CAP of FIGS. 9 to 11 may be formed simultaneously with the capacitor structures CAP of FIGS. 2 to 8.

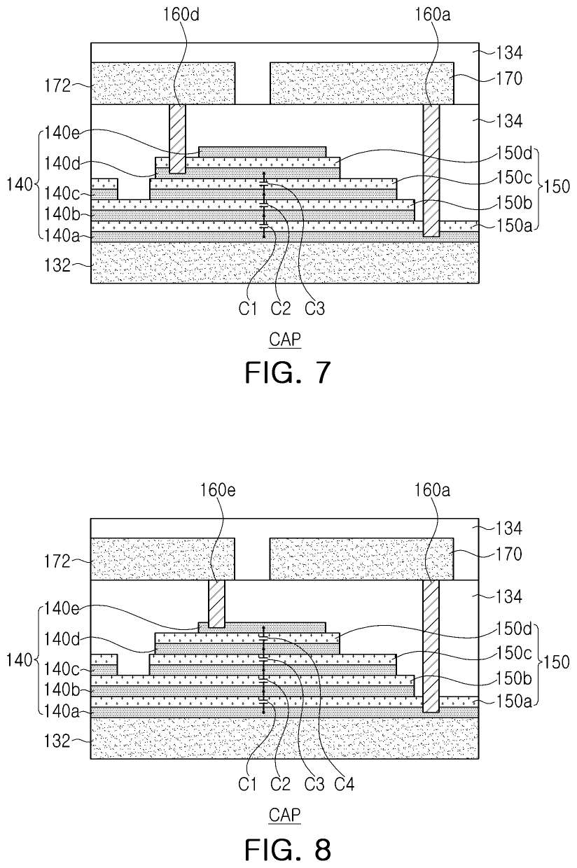

FIG. 12 is a cross-sectional view of a semiconductor device according to an example embodiment.

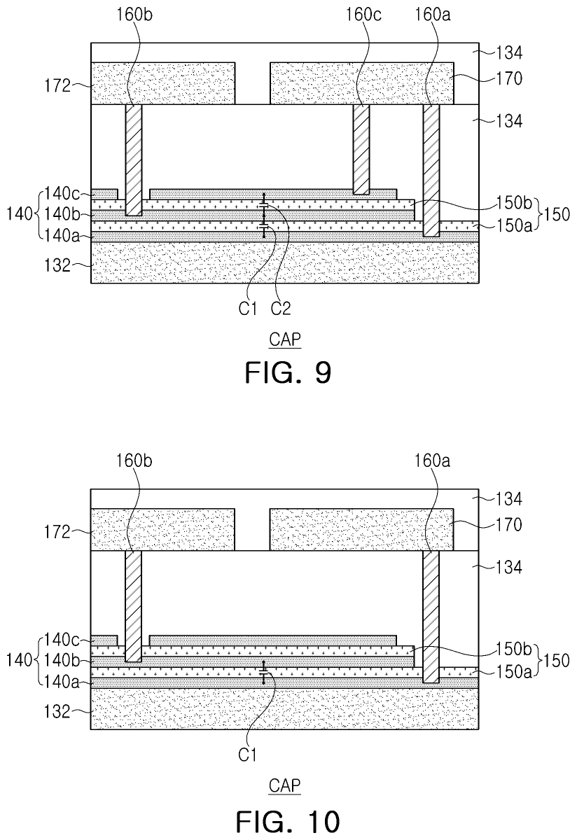

Referring to FIG. 12, a semiconductor device 200 may include a capacitor structure CAP disposed in an interconnection layer 120. In an embodiment, the semiconductor device 200 may further include a resistance structure R disposed in the interconnection layer 120. The resistance structure R may be disposed on the same vertical level as the capacitor structure CAP. However, the arrangement and the number of resistance structures R illustrated in FIG. 12 is merely an example, and are not limited thereto. In some embodiments, a plurality of capacitor structures CAP and a plurality of resistance structures R may be disposed in the interconnection layer 120. For example, the capacitor structure CAP may be disposed between two resistance structures R. FIG. 13 illustrates a resistance structure according to an example embodiment.

Referring to FIG. 13, a resistance structure R may include electrode layers 140, dielectric layers 150, resistance connectors 260, a first resistance terminal 270, a first connection portion 272, a second connection portion 274, and a second resistance terminal 276. The electrode layers 140 and the dielectric layers 150 may have the same or similar structures as the electrode layers 140 and the dielectric layers 150 of the capacitor structure CAP illustrated in FIGS. 2 to 9. For example, the resistance structure R may include three or more electrode layers 140.

The resistance connectors 260 may extend vertically through an interlayer insulating layer 134, and may be in contact with one of the electrode layers 140 corresponding thereto, respectively. For example, a first resistance connector 260a and a second resistance connector 260b may be in contact with a first electrode layer 140a, a third resistance connector 260c and a fourth resistance connector 260d may be in contact with a second electrode layer 140b, and a fifth resistance connector 260e and a sixth resistance connector 26Of may be in contact with a third electrode layer 140c. Some of the resistance connectors 260 may pass through a dielectric layer 150 disposed on an electrode layer 140.

The first resistance terminal 270, the first connection portion 272, the second connection portion 274, and the second resistance terminal 276 may be disposed on the same vertical level as at least one of conductive interconnections 130. The first resistance terminal 270, the first connection portion 272, the second connection portion 274, and the second resistance terminal 276 may be disposed on the resistance connectors 260, and may be connected to the resistance connectors 260. For example, the first resistance terminal 270 may be electrically connected to the first electrode layer 140a through the first resistance connector 260a. The first connection portion 272 may be electrically connected to the first electrode layer 140a and the second electrode layer 140b through the second resistance connector 260b and the third resistance connector 260c. The second connection portion 274 may be electrically connected to the second electrode layer 140b and the third electrode layer 140c through the fourth resistance connector 260d and the fifth resistance connector 260e. The second resistance terminal 276 may be electrically connected to the third electrode layer 140c through the sixth resistance connector 260f. Therefore, the electrode layers 140 and the resistance connectors 260 connected thereto may be connected in series between the first resistance terminal 270 and the second resistance terminal 276 to form a resistance structure R. Therefore, a resistance structure R including three or more electrode layers 140 as in embodiments of the present inventive concept may have higher resistance, as compared to a resistance structure R including two electrode layers 140.

In an embodiment, the resistance structure R may be formed simultaneously with the capacitor structures CAP illustrated in FIGS. 2 to 11. For example, the electrode layer 140 and the dielectric layer 150 of the resistance structure R may be disposed on the same vertical level as the electrode layer 140 and the dielectric layer 150 of the capacitor structure CAP illustrated in FIGS. 2 to 11, respectively. In an embodiment, the resistance structure R may be electrically connected to one of the capacitor structures CAP. In an embodiment, the resistance structure R may be electrically connected to the transistor T disposed on the device layer 110.

In an embodiment, the resistance structure R may further include a lower interconnection 132. An electrode layer 140, which may be is the lowermost electrode layer, may be disposed on an upper surface of the lower interconnection 132. The lower interconnection 132 may be electrically connected to the electrode layer 140, which may be is the lowermost electrode layer, and may function as a resistance interconnection of the resistance structure R. The lower interconnection 132 may include the same material as the conductive interconnections 130, and may have substantially the same vertical thickness. In addition, the lower interconnection 132 may be located on the same vertical level as at least one of the conductive interconnections 130.

In an embodiment, the electrode layer 140 of the resistance structure R may include a material, different from a material of the conductive interconnection 130. For example, the conductive interconnection 130 may include aluminum (Al) or copper (Cu), and the electrode layer 140 may include titanium nitride (TiN). The specific resistance of aluminum (Al) may be about 2.8×10⁻⁶ ohm·cm, and specific resistance of copper (Cu) may be about 1.7×10⁻⁶ ohm·cm. The specific resistance of titanium nitride (TiN) may be about 200×10⁻⁶ ohm·cm. Therefore, compared to a case in which a resistance interconnection is formed with the conductive interconnection 130, when the electrode layer 140 is used, the resistance interconnection having a large resistance may be formed in a smaller area. In addition, since the resistance structure R is disposed in the interconnection layer 120, a size of the device layer 110 may not increase, as compared to a case in which the resistance interconnection is formed of a material such as polysilicon in the device layer 110. Therefore, the size of the semiconductor device 200 may be reduced. In addition, since titanium nitride (TiN) has better electromigration (EM) characteristics than metals such as aluminum (Al) or copper (Cu), a higher current may be transmitted and a melting phenomenon may be prevented. Therefore, reliability of the semiconductor device 200 may be further improved.

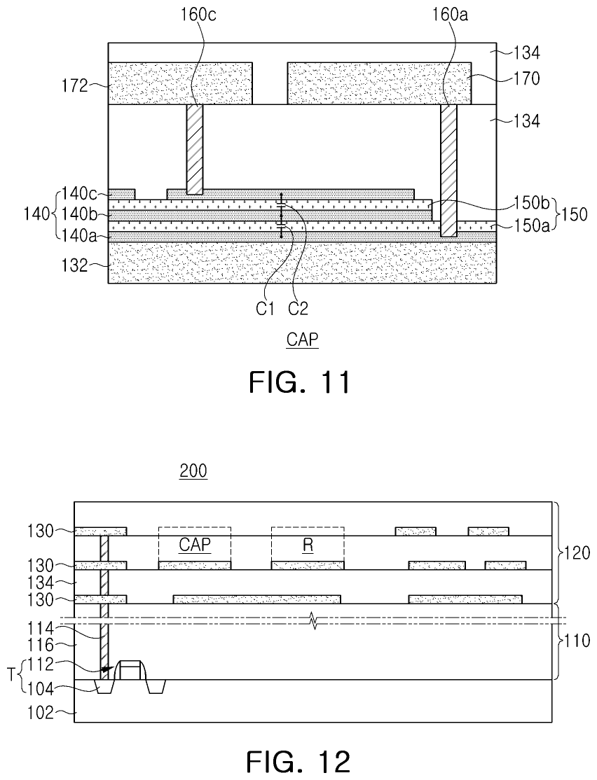

FIG. 14 is a cross-sectional view of a semiconductor device according to an example embodiment.

Referring to FIG. 14, a semiconductor device 300 may include capacitor structures CAP and resistance structures R, disposed in an interconnection layer 120. In an embodiment, some of the capacitor structures CAP may be disposed on different vertical levels. In addition, some of the resistance structures R may be disposed on different vertical levels. A resistance structure R illustrated in FIG. 14 may have the same or similar structure as the resistance structure R illustrated in FIG. 13.

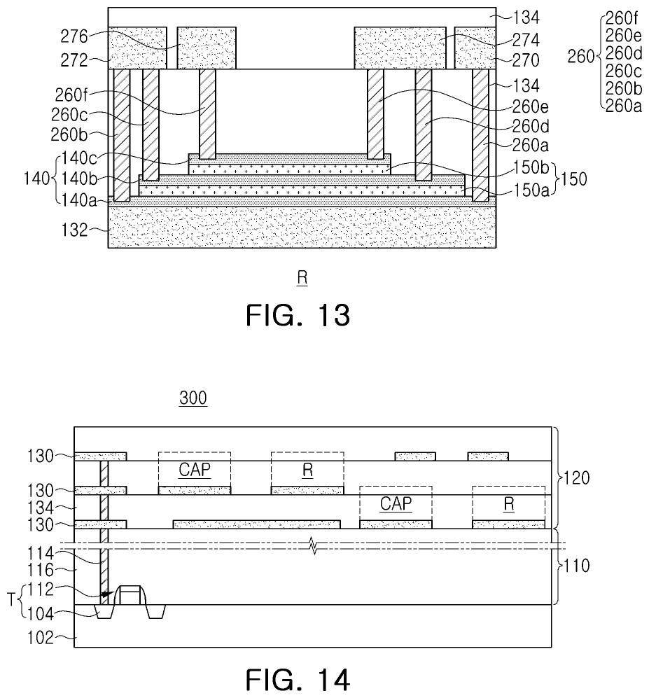

FIG. 15 is a configuration diagram illustrating a semiconductor integrated circuit device including a semiconductor device according to an embodiment. FIG. 15 illustrates an electrostatic discharge (ESD) protection circuit, and may include the semiconductor device illustrated in FIGS. 1, 12, and 13.

Referring to FIG. 15, a semiconductor integrated circuit device 1000 according to an embodiment may include an input/output pad 1100, an electrostatic discharge protection circuit 1200, an input buffer 1300, and a data processor P. In addition, the semiconductor integrated circuit device 1000 may further include a charge device model (CDM) protection circuit 1400 that protects a CDM. The input/output pad 1100 may receive an input signal transmitted from an external source, and may transmit a processed output signal to the external source. For example, the input/output pad 1100 may transmit and receive a signal to and from the data processor P. The signal transmitted through the input/output pad 1100 may be stored in the input buffer 1300 to wait for a command of the data processor P or may be pre-processed as a signal suitable for the data processor P. In an embodiment, the input/output pad 1100 may include an output pad of a display driver integrated circuit (DDI) device that drives a display panel. In an embodiment, the data processor P may include a display panel.

The electrostatic discharge protection circuit 1200 may protect the data processor P by grounding an electrostatic discharge current. For example, when an electrostatic discharge current exceeding an allowable range is applied to the data processor P from the input/output pad 1100, the electrostatic discharge protection circuit 1200 may discharge the discharge current to a ground, to prevent damage to the data processor P.

The electrostatic discharge protection circuit 1200 may include at least one transistor T1, a capacitor CAP, a resistor R electrically connected to the capacitor CAP, a discharge line 1260 connected to the input/output pad 1100 and the resistor R to induce an electrostatic discharge current to the transistor T1, and a ground line 1270 connected to the transistor T1 to ground the induced electrostatic discharge current. In an embodiment, the capacitor CAP may include three or more electrode layers, and may have the same or similar structure as the capacitor structure CAP illustrated in FIGS. 2 to 11. In an embodiment, the resistor R may include three or more electrode layers, and may have the same or similar structure as the resistance structure R illustrated in FIG. 13. In an embodiment, the transistor T1 may correspond to the transistor T illustrated in FIG. 1, FIG. 12, or FIG. 14.

When a normal signal is applied from the input/output pad 1100, the transistor T1 may be short-circuited (switched off), and may not affect an operation of the semiconductor integrated circuit device 1000. The input signal may be transmitted to the input buffer 1300, and may be applied to the data processor P.

When an electrostatic discharge current is applied from the input/output pad 1100, due to a punch-through in which a drain region D of the transistor T1 and a source region S of the transistor T1 are connected, the electrostatic discharge current may directly flow into the source region S. Therefore, the electrostatic discharge current may be grounded through a ground terminal GRD, to protect the data processor P from the electrostatic discharge current. The resistor R may function as a protection resistor that protects the transistor T1 by preventing the discharge current flowing along the discharge line 1260 from excessively flowing into the transistor T1.

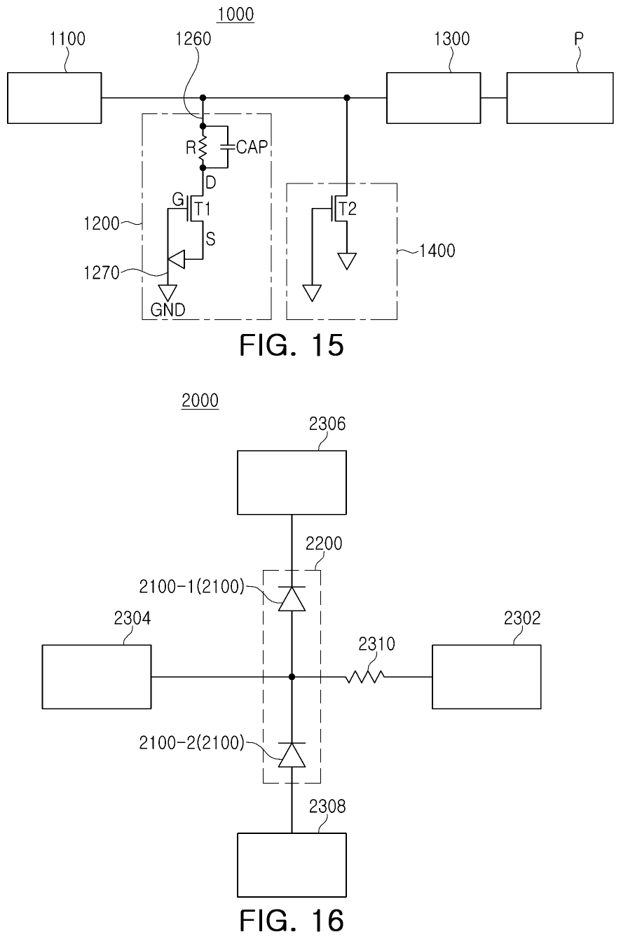

FIG. 16 is a configuration diagram illustrating a semiconductor integrated circuit device including a semiconductor device according to an embodiment. FIG. 16 illustrates an electrostatic discharge protection circuit, and may include the semiconductor device illustrated in FIGS. 1, 12, and 13.

Referring to FIG. 16, a semiconductor integrated circuit device 2000 according to an embodiment may include an input/output pad 2304, an electrostatic discharge protection circuit 2200, a power pad 2306, a ground pad 2308, and a protection-targeted device 2302. The protection-targeted device 2302 may include a data processor P, as described with reference to FIG. 15, and may include, for example, a display panel.

The electrostatic discharge protection circuit 2200 may be disposed between the input/output pad 2304 and the protection-targeted device 2302, and may include a first diode 2100-1 and a second diode 2100-2, connected in series. The first diode 2100-1 may have a P-type diode structure, and the second diode 2100-2 may have an N-type diode structure.

An anode terminal of the first diode 2100-1 may be electrically connected to the input/output pad 2304, and a cathode terminal of the first diode 2100-1 may be electrically connected to the power pad 2306. An anode terminal of the second diode 2100-2 may be electrically connected to the ground pad 2308, and a cathode terminal of the second diode 2100-2 may be electrically connected to the input/output pad 2304. The input/output pad 2304 may be electrically connected to the protection-targeted device 2302 to apply a signal voltage, and may be connected to an anode of the first diode 2100-1 and a cathode of the second diode 2100-2 in common.

The semiconductor integrated circuit device 2000 may include the electrostatic discharge protection circuit 2200 to prevent an electrostatic discharge current from flowing to the protection-targeted device 2302. In some embodiments, an electrostatic discharge current may flow into the semiconductor integrated circuit device 2000 through the input/output pad 2304. In some embodiments, a positive (+) electrostatic discharge current may flow in a forward direction of the first diode 2100-1 (i.e., forward biased), and may flow from a terminal to which a power supply voltage Vdd is applied. In this case, the second diode 2100-2 may be reverse biased, and the positive electrostatic discharge current may be cut off from flowing in a reverse direction by the second diode 2100-2. In some embodiments, when a negative (−) electrostatic discharge current is applied, the negative (−) electrostatic discharge current may flow in a forward direction of the second diode 2100-2, and may flow from a terminal to which a ground voltage Vss is applied. In this case, the first diode 2100-1 may be biased in a reverse direction, and may block the negative (−) electrostatic discharge current from flowing in the reverse direction.

The electrostatic discharge protection circuit 2200 may further include a resistor 2310. The resistor 2310 may connect the first diode 2100-1 and the second diode 2100-2 to the protection-targeted device 2302. The resistor 2310 may be connected to the front end of the protection-targeted device 2302 to more safely protect the protection-targeted device 2302. In an embodiment, the resistor 2310 may include three or more electrode layers, and may have the same or similar structure as the resistance structure R illustrated in FIG. 13.

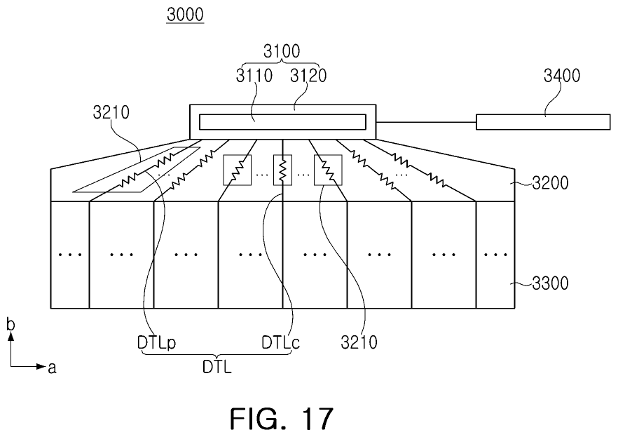

FIG. 17 is a configuration diagram illustrating a semiconductor integrated circuit device including a semiconductor device according to an embodiment. FIG. 17 illustrates a fan-out compensation resistor, and may include the semiconductor device illustrated in FIGS. 1, 12, and 13.

A semiconductor integrated circuit device 3000 according to an embodiment may include a display driving integrated circuit device 3100, a display panel 3300, and a fan-out resistor 3200. The semiconductor integrated circuit device 3000 may further include an electrostatic discharge current protection circuit 3400. The electrostatic discharge current protection circuit 3400 may have the same or similar structure as the electrostatic discharge protection circuit 1200 or the electrostatic discharge protection circuit 2200 described with reference to FIGS. 16 and 17.

The display driving IC device 3100 may include at least one of a gate driving integrated circuit device or a data driving integrated circuit device. The display driving IC device 3100 may include a driving chip 3110 and a circuit board 3120. The driving chip 3110 may process an image data signal input from an external source, to generate a data signal supplied to each data line DTL of the display panel 3300. The circuit board 3120 may transmit signals between the driving chip 3110 and the display panel 3300. The circuit board 3120 may include the fan-out resistor 3200 between the driving chip 3110 and the display panel 3300. The fan-out resistor 3200 may compensate for a difference in interconnection resistance due to a length variation of the data line DTL to make intensity of the data signal uniformly.

The display panel 3300 may include a plurality of data lines DTL extending in a vertical direction b, and a plurality of gate lines extending in a horizontal direction a. An interconnection length of a central portion data transmission line DTLc connected to a central portion of the display panel 3300 may be shorter than an interconnection length of a peripheral portion data transmission line DTLp connected to a peripheral portion of the display panel 3300. Therefore, current loss of the data signal transmitted along the peripheral portion data transmission line DTLp may be greater than current loss of the data signal transmitted along the central portion data transmission line DTLc, and luminance of the display panel 3300 may be reduced in the peripheral portion.

Since the semiconductor integrated circuit device 3000 according to an example embodiment may include the fan-out resistor 3200, a difference in interconnection resistance due to a length variation of the data line DTL may be compensated for to uniformly intensify the data signal. For example, the fan-out resistor 3200 may include a compensation resistor 3210 disposed on the data line DTL, and the compensation resistor 3210 may cause the same current loss in all data lines DTL. An additional resistor may be provided as a compensation resistor for each data line DTL to be compensated for.

In an embodiment, the compensation resistor 3210 may have the same or similar configuration as the semiconductor device illustrated in FIG. 12 or 14. For example, the compensation resistor 3210 may include a resistance structure R including three or more electrode layers 140 illustrated in FIG. 13. Since the resistance structure R may include three or more electrode layers 140, resistance devices having various resistances may be implemented using the electrode layers 140 and the resistance connector 260. Therefore, since the compensation resistor 3210 may implement various resistances, the fan-out resistor 3200 may compensate for a difference in interconnection resistance due to a length variation of the data line DTL to make intensity of the data signal uniformly.

According to embodiments of the present inventive concept, since a capacitor structure includes three or more electrode layers, various capacitances may be implemented. Therefore, a high-density capacitor structure or a capacitor structure having a high internal voltage may be implemented.

According to embodiments of the present inventive concept, since a resistance structure may include three or more electrode layers, various resistances may be implemented. Therefore, a resistance structure having a resistance, higher than a resistance of a resistance device, formed in a device layer, may be implemented.

While example embodiments have been illustrated and described above, it will be apparent to those skilled in the art that modifications and variations could be made thereto without departing from the scope of the present inventive concept as set forth in the appended claims.

What is claimed is:

1. A semiconductor device comprising:
a device layer on a substrate;
an interconnection layer disposed on the device layer, wherein the interconnection layer includes conductive interconnections forming a plurality of layers; and
first and second capacitor structures disposed inside the interconnection layer,
wherein each of the first and second capacitor structures includes:
electrode layers spaced apart from each other in a vertical direction and forming three or more layers;
dielectric layers between the electrode layers;
conductive vias respectively connected to one of the electrode layers and extending vertically;
a first connection terminal electrically connected to a lowermost electrode layer; and
a second connection terminal electrically connected to at least one of the electrode layers,
wherein the first capacitor structure and the second capacitor structure include the same number of electrode layers, and wherein a first capacitance of the first capacitor structure is different from a second capacitance of the second capacitor structure.

2. The semiconductor device of claim 1, wherein the electrode layers comprise a material different from a material of the conductive interconnections.

3. The semiconductor device of claim 2, wherein the electrode layers comprise titanium nitride.

4. The semiconductor device of claim 2, wherein a specific resistance of the electrode layers is greater than a specific resistance of the conductive interconnections.

5. The semiconductor device of claim 1, wherein the dielectric layers comprise silicon nitride.

6. The semiconductor device of claim 1, wherein a second connection terminal included in the first capacitor structure is in contact with a plurality of conductive vias.

7. The semiconductor device of claim 1, wherein the conductive interconnections comprise lower interconnections,
wherein the capacitor structures are disposed on upper surfaces of the lower interconnections.

8. The semiconductor device of claim 1, wherein the first capacitor structure is located on a different vertical level from the second capacitor structure.

9. The semiconductor device of claim 1, wherein at least one of electrode layers included in the first capacitor structure is not electrically connected to the first connection terminal and the second connection terminal.

10. The semiconductor device of claim 1, wherein the number of conductive vias included in the first capacitor structure is different from the number of conductive vias included in the second capacitor structure.

11. The semiconductor device of claim 1, wherein the semiconductor device further comprises a third capacitor structure,
wherein the number of electrode layers included in the third capacitor structure is different from the number of electrode layers included in the first capacitor structure, and
a third capacitance of the third capacitor structure is different from the first capacitance and the second capacitance.

12. The semiconductor device of claim 1, further comprising a resistance structure disposed inside the interconnection layer,
wherein the resistance structure includes:
electrode layers spaced apart from each other in a vertical direction and forming three or more layers;
dielectric layers between the electrode layers;
resistance connectors each connected to one of the electrode layers and extending vertically;
a first resistance terminal electrically connected to a lowermost electrode layer of the resistance structure;
a second resistance terminal electrically connected to an uppermost electrode layer of the resistance structure; and
connection portions between the first resistance terminal and the second resistance terminal.

13. The semiconductor device of claim 12, wherein the first resistance terminal, the second resistance terminal, and the connection portions are disposed on the same vertical level as at least one of the conductive interconnections.

14. The semiconductor device of claim 12, wherein the electrode layers of the resistance structure are disposed on the same vertical level as at least one electrode layer of the capacitor structures.

15. A semiconductor integrated circuit device comprising:
an input/output pad;
a data processor configured to transmit and receive a signal to and from the input/output pad; and
an electrostatic discharge protection circuit connecting the input/output pad and the data processor,
wherein the electrostatic discharge protection circuit includes:
a device layer on a substrate;
an interconnection layer disposed on the device layer, wherein the interconnection layer includes conductive interconnections forming a plurality of layers;
capacitor structures disposed inside the interconnection layer; and
resistance structures disposed inside the interconnection layer,
wherein each of the capacitor structures includes electrode layers spaced apart from each other in a vertical direction and forming three or more layers, and dielectric layers between the electrode layers,
the capacitor structures include a first capacitor structure and a second capacitor structure, having different capacitances, and
each of the resistance structures includes electrode layers spaced apart from each other in a vertical direction and forming three or more layers, and dielectric layers between the electrode layers of the resistance structure.

16. The semiconductor integrated circuit device of claim 15, wherein the first capacitor structure and the second capacitor structure includes the same number of electrode layers.

17. The semiconductor integrated circuit device of claim 15, wherein the data processor comprises a display panel,
wherein the input/output pad includes an output pad of a display driving integrated circuit device for driving the display panel.

18. The semiconductor integrated circuit device of claim 17, further comprising a fan-out resistor connected to the display driving integrated circuit device to compensate for a resistance variation in data lines applying a data signal to each of the data lines of the display panel.

19. The semiconductor integrated circuit device of claim 18, wherein the fan-out resistor comprises a resistance compensator disposed on each of the data lines,
wherein the resistance compensator includes electrode layers spaced apart from each other in a vertical direction and forming three or more layers, and dielectric layers between the electrode layers.

20. A semiconductor device comprising:
a device layer on a substrate;
an interconnection layer disposed on the device layer, and including conductive interconnections forming a plurality of layers; and
capacitor structures and resistance structures, disposed on the same vertical level inside the interconnection layer,
wherein each of the capacitor structures includes electrode layers spaced apart from each other in a vertical direction and forming three or more layers, and a first connection terminal and a second connection terminal, disposed on the electrode layers and electrically connected to at least one of the electrode layers,
each of the resistance structures includes electrode layers spaced apart from each other in a vertical direction and forming three or more layers, and a first resistance terminal and a second resistance terminal, disposed on the electrode layers of the resistance structure and electrically connected to at least one of the electrode layers of the resistance structure,
the first connection terminal, the second connection terminal, the first resistance terminal, and the second resistance terminal are disposed on the same vertical level as each other,
the capacitor structures include a first capacitor structure and a second capacitor structure, including the same number of electrode layers, and
a first capacitance of the first capacitor structure is different from a second capacitance of the second capacitor structure.
